(19) United States
(12) Patent Application Publication
(10) Pub. No.: US 2026/0047492 A1
(43) Pub. Date: Feb. 12, 2026

(54) SEMICONDUCTOR PACKAGE ASSEMBLY

(71) Applicant: MEDIATEK INC., Hsinchu City (TW)

(72) Inventors: Tai-Yu CHEN, Hsinchu City (TW); Yih-Ting SHEN, Hsinchu City (TW); Yu-Jin LI, Hsinchu City (TW); Ping-Yeh LIN, Hsinchu City (TW); Chun-Yi CHANG, Hsinchu City (TW)

(21) Appl. No.: 19/222,058

(22) Filed: May 29, 2025

Related U.S. Application Data
(60) Provisional application No. 63/679,669, filed on Aug. 6, 2024.

(51) Int. Cl. H01L 25/18; H01L 23/00; H01L 23/24; H01L 23/31; H05K 1/18; H10B 80/00; H10D 80/30

(52) U.S. Cl. CPC H01L 25/18; H01L 24/32; H01L 23/24; H01L 23/3157; H01L 24/16; H01L 24/73; H01L 2224/16227; H01L 2224/32225; H01L 2224/73204; H01L 2924/1431; H01L 2924/14361; H05K 1/181; H10B 80/00; H10D 80/30

(57) ABSTRACT

A semiconductor package assembly is provided. The semiconductor package assembly includes a substrate, an interposer, a first die, a second die, and a dummy die structure. The interposer is disposed on the substrate. The interposer includes a central region and a peripheral region. The peripheral region includes a corner region and a non-corner region. The first die is disposed on the interposer in the central region. The second die is disposed beside the first die and is located in the non-corner region of the peripheral region of the interposer. The dummy die structure is disposed beside the first die and the second die and is located in the corner region of the peripheral region of the interposer. The dummy die structure includes dummy dies stacked on each other in a first direction.

### CROSS REFERENCE TO RELATED APPLICATIONS

This application claims the benefit of U.S. Provisional Application No. 63/679,669, filed on Aug. 6, 2024, the entirety of which is incorporated by reference herein.

### BACKGROUND OF THE DISCLOSURE

### Field of the Disclosure

The present disclosure relates to a semiconductor package assembly, and, in particular, it relates to a semiconductor package assembly having dummy dies.

### Description of the Related Art

It is widely known in the art that a Chip-on-Wafer-on-Substrate (CoWoS) is a 2.5D wafer-level multi-chip packaging technology that incorporates multiple dies side-by-side on a silicon interposer substrate in order to achieve better interconnect density and performance. Individual chips are bonded through micro-bumps on the silicon interposer substrate forming a chip-on-wafer (CoW). The CoW is then subsequently thinned so that the through substrate via (TSV) perforations are exposed. Formation and singulation of C4 bumps are then carried out. A CoWoS package is completed by being bonded to a package substrate.

Although existing semiconductor package assemblies have generally been adequate, they are not satisfactory in all respects. For example, conventional CoWoS packages have a drawback in that there may be stress on the package corners during or after reliability testing. Stress failures may cause reliability issues. Therefore, there is a need to further improve the reliability of semiconductor package assemblies.

### BRIEF SUMMARY OF THE DISCLOSURE

An embodiment of the present disclosure provides a semiconductor package assembly. The semiconductor package assembly includes a substrate, an interposer, a first die, a second die, and a dummy die structure. The interposer is disposed on the substrate. The interposer includes a central region and a peripheral region. The peripheral region includes a corner region and a non-corner region. The first die is disposed on the interposer in the central region. The second die is disposed beside the first die and is located in the non-corner region of the peripheral region of the interposer. The dummy die structure is disposed beside the first die and the second die and is located in the corner region of the peripheral region of the interposer. The dummy die structure includes dummy dies stacked on each other in a first direction.

### BRIEF DESCRIPTION OF THE DRAWINGS

The present disclosure can be more fully understood by reading the subsequent detailed description and examples with references made to the accompanying drawings, wherein:

FIG. 1 is a schematic top view of a semiconductor package assembly in accordance with some embodiments of the disclosure, showing the arrangement of dies of the semiconductor package assembly in accordance with some embodiments of the disclosure;

FIG. 2 is a cross-sectional view taken along the line A-A′ of FIG. 1;

FIG. 3 is a cross-sectional view taken along the line B-B′ of FIG. 1;

FIG. 4 is a schematic top view of a semiconductor package assembly in accordance with some embodiments of the disclosure, showing the arrangement of dies of the semiconductor package assembly in accordance with some embodiments of the disclosure;

FIG. 5 is a schematic top view of a semiconductor package assembly in accordance with some embodiments of the disclosure, showing the arrangement of dies of the semiconductor package assembly in accordance with some embodiments of the disclosure;

FIG. 6 is a cross-sectional view taken along the line C-C′ of FIG. 4 or the line B-B′ of FIG. 5;

FIG. 7 is a cross-sectional view taken along the line C-C′ of FIG. 4 or the line B-B′ of FIG. 5;

FIG. 8 is a schematic top view of a semiconductor package assembly in accordance with some embodiments of the disclosure, showing the arrangement of dies of a semiconductor package assembly in accordance with some embodiments of the disclosure;

FIG. 9 is a cross-sectional view taken along the line B-B′ of FIG. 8; and

FIG. 10 is a cross-sectional view taken along the line B-B′ of FIG. 8.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items. The term “dummy die”, which is a non-function die, is referred to as a semiconductor die or chip that does not have any electrical function.

In the semiconductor package structure, a dummy silicon die is used to adjust the floor plan structure. However, as the size of the semiconductor package increases, the stress of the semiconductor package also increases, especially at the corners of the semiconductor package. Placing block dummy dies at the corner of the semiconductor package can lead to stress concentration and result in poorer reliability. For example, due to the hard stiffness of the block dummy die in the conventional semiconductor package, the stress hot zone concentrates on the edge of the dummy die. Additionally, the dummy die is usually located on the corner of the semiconductor package, which experiences higher stress during reliability testing. Therefore, there is a need to further improve semiconductor package assemblies to reduce the stress of the semiconductor package.

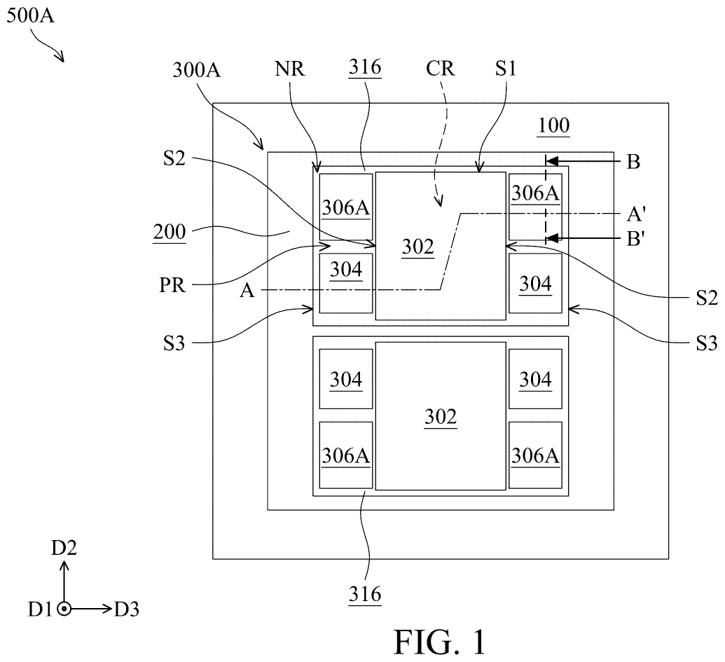

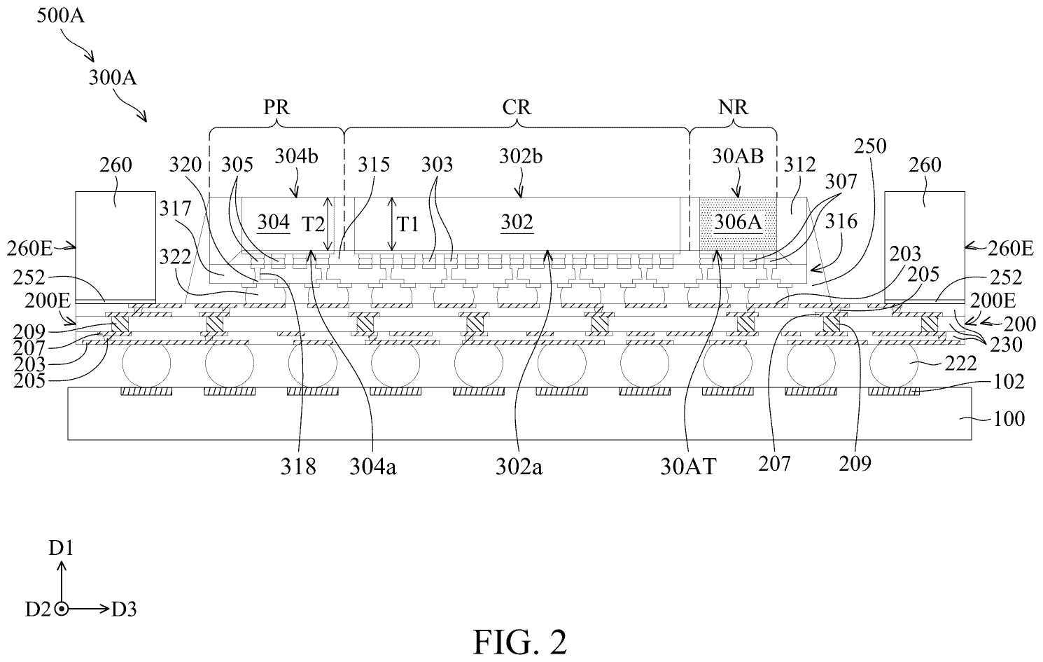

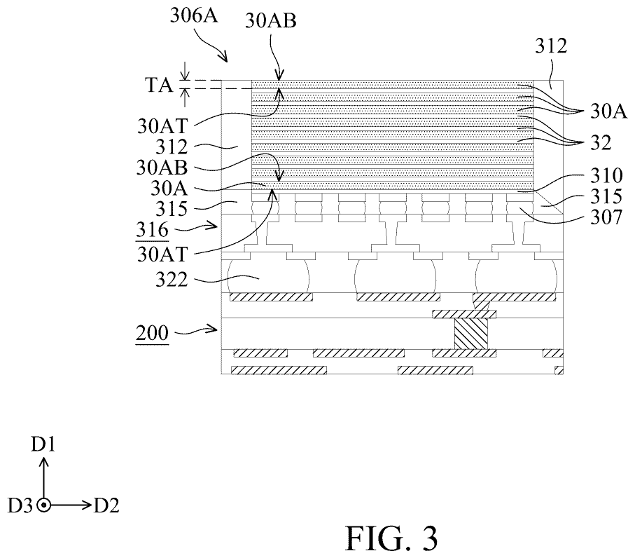

FIG. 1 is a schematic top view of a semiconductor package assembly 500A in accordance with some embodiments of the disclosure, showing the arrangement of dies of the semiconductor package assembly 500A in accordance with some embodiments of the disclosure. FIG. 2 is a cross-sectional view taken along the line A-A′ of FIG. 1. FIG. 3 is a cross-sectional view taken along line B-B′ of FIG. 1. For illustration, an underfill, a molding compound and a stiffener ring covering an interposer 316 of a fan-out package 300A of the semiconductor package assembly 500A are omitted in FIG. 1.

In some embodiments, the semiconductor package assembly 500A can be used to form a Chip-on-Wafer-on-Substrate (CoWoS) structure. The semiconductor package assembly 500A may include at least one wafer-level fan-out package 300A (such as a Chip-on-Wafer (CoW) package) and a substrate 200. The fan-out package 300A is mounted on a substrate 200. In addition, the substrate 200 is mounted on a base 100. In some embodiments, the semiconductor package assembly 500A may not include the base 100; that is, the base 100 is external to the semiconductor package assembly 500A.

As shown in FIG. 1, the base 100, for example a printed circuit board (PCB), may be formed of polypropylene (PP). It should also be noted that the base 100 can be a single layer or a multilayer structure. A plurality of pads 102 and/or conductive traces (not shown) is disposed on the base 100. The pads 102 are used for the semiconductor package assembly 500A that is mounted directly on them. In some embodiments, the pads 102 are connected to different terminals of the conductive traces. The conductive traces may include signal trace segments or ground trace segments, which are used for the input/output (I/O) connections of the fan-out package 300A. In some other embodiments, the fan-out package 300A is mounted directly on the conductive traces.

As shown in FIG. 2, the substrate 200 may serve as a fan-out structure for the overlying fan-out package 300A. In some embodiments, the substrate 200 includes a core substrate or a coreless substrate. The core substrate includes a core (not shown) that may be made of woven glass layers pre-impregnated with an epoxy resin material, such as the prepreg laminate FR-4 commonly used for printed circuit boards. In some embodiments, the substrate 200 includes one or more conductive routings disposed therein. In some embodiments, the conductive routings include one or more conductive pads 203, conductive vias 205, conductive traces 207 and conductive pillars 209 disposed in one or more dielectric build-up layers 230. In some embodiments, the conductive pads 203, the conductive vias 205, the conductive traces 207 and the conductive pillars 209 include a conductive material, such as metals comprising copper, gold, silver, or other applicable metals. In some embodiments, the dielectric build-up layers 230 may be formed of organic materials, which include a polymer base material, non-organic materials, which include extra-low K (ELK) dielectrics and/or ultra-low K (ULK) dielectric, or the like. For example, the dielectric layers are made of a polymer base material. However, it should be noted that the number and configuration of the dielectric build-up layers 230, the conductive pads 203, the conductive vias 205, the conductive traces 207 and the conductive pillars 209 shown in FIG. 2 are only an example and is not a limitation to the present disclosure.

As shown in FIG. 2, conductive structures 222 are disposed between the substrate 200 and the base 100. The conductive structures 222 are disposed on the substrate 200 away from the fan-out package 300A and in contact with the conductive pads 203 of the substrate 200 and the corresponding contact pads 102 of the base 100. Therefore, the substrate 200 is electrically connected to the base 100 via the conductive structures 222. In some embodiments, the conductive structures 222 comprise a conductive ball structure such as a copper ball, a conductive bump structure such as a copper bump or a solder bump structure, or a conductive pillar structure such as a copper pillar structure.

As shown in FIGS. 1 and 2, the fan-out package 300A (also called the CoW package 300A) is mounted on the substrate 200 opposite the conductive structures 222 by a bonding process using conductive structures 322. The fan-out package 300A includes a first die 302, a second die 304, a dummy die structure 306A, an interposer 316, a molding compound 312, and the conductive structures 322.

The conductive structures 322 are in contact with and electrically connected (or coupled) to the interposer 316 and the conductive pads 203 of the substrate 200. In some embodiments, the conductive structures 322 comprise a conductive ball structure such as a copper ball, a conductive bump structure such as a copper bump or a solder bump structure, or a conductive pillar structure such as a copper pillar structure. For example, the conductive structures 322 may be controlled collapse chip connection (C4) structures.

As shown in FIGS. 1 and 2, one or more interposers 316 are disposed on the substrate 200. It should be noted that the number of interposers 316 shown in FIG. 1 can be adjusted according to the design requirements of the products, and is not limited to the disclosed embodiments. The interposer 316 has a central region CR and a peripheral region PR, wherein the peripheral region PR further has a corner region NR and a non-corner region, the central region CR, the non-corner region and the corner region NR are provided for a first die 302, a second die 304, a dummy die structure 306A mounted on them respectively. In some embodiments, the interposer 316 may include one or more conductive traces (not shown), one or more conductive vias 318 disposed in one or more dielectric layers 317 and conductive pads 320. The conductive traces are electrically connected (or coupled) to the corresponding contact pads 320. The contact pads 320 are exposed to openings of the solder mask layer (not shown) and close to the substrate 200. The conductive elements 322 are disposed on and in contact with the corresponding contact pads 320. Therefore, the conductive elements 322 are electrically connected (or coupled) between the contact pads 320 of the fan-out package 300A and the conductive pads 203 of the substrate 200.

In some embodiments, the material of the conductive vias 318, the conductive traces and the contact pads 320 of the interposer 316 may be similar to the material of the conductive vias 205, the conductive traces 207 and the conductive pads 203. In addition, the material of the dielectric layers 317 may be similar to the material of the dielectric build-up layers 230. It should be noted that in the interposer 316, the number of conductive vias 318, the number of conductive traces, the number of conductive pads 320 and the number of dielectric layers 317 shown in FIG. 2 are only an example and is not a limitation to the present disclosure.

As shown in FIGS. 1 and 2, the first die 302 is disposed on the interposer 316 and in the central region CR. The second die 304 is disposed beside the first die and located in the non-corner region of the peripheral region PR of the interposer 316. In addition, a dummy die structure 306A is disposed beside the first die 302 and the second die 304 and is located in the corner region NR of the peripheral region PR of the interposer 316. In some embodiments, the first die 302, the second die 304 and the dummy die structure 306A may have a rectangular shaped die arrangement. For example, the total number of the first die 302, the second die 304 and the dummy die structure 306A having the rectangular shaped die arrangement may be at least five. The five dies may include, one first die 302 having a shorter edge S1 and a longer edge S2, two smaller, second dies 304 disposed along the longer edge S2 of the first die 302, and two dummy die structures 306A disposed at the respective two corners. It is noted that the arrangement of dummy die structure 306A is not limited to the disclosed embodiment.

In some embodiments, the second dies 304 and the dummy die structures 306A are disposed adjacent to a longer edge S2 of the first die 302 and located between the longer edge S2 of the first die 302 and an edge S3 of the interposer 316.

In some embodiments, the first die 302 has an active surface 302a and a backside surface 302b. The backside surface 302b is opposite the active surface 302a. The second die 304 has an active surface 304a and a backside surface 304b. The backside surface 304b is opposite the active surface 304a. In some embodiments, the first die 302 and the second die 304 are fabricated by a flip-chip technology and flipped to be disposed on the interposer 316 opposite the conductive structures 322.

In some embodiments, the first die 302 includes a logic die. For example, the logic die may include a system-on-chip (SoC), a central processing unit (CPU) die, a graphic processing unit (GPU) die, a radio frequency (RF) die, a micro control unit (MCU) die, a microprocessor unit (MPU) die, a power management integrated circuit (PMIC) die, a global positioning system (GPS) device, or an application processor (AP) die, or any combination thereof.

In some embodiments, the second die 304 includes a memory die. For example, the memory die may include a dynamic random access memory (DRAM) die, a high bandwidth memory (HBM) die, the like, or any combination thereof. For example, the second die 304 may be HBM2 or HBM3, but not limited thereto. HBM is a memory chip with low power consumption and ultra-wide communication lanes.

As shown in FIGS. 1-3, the dummy die structure 306A may include dummy dies 30A stacked on each other in a direction D1 (i.e., the vertical direction). Each of the dummy dies 30A has an active surface 30AT and a backside surface 30AB. The backside surface 30AB is opposite the active surface 30AT. In some embodiments, each of the dummy dies 30A is fabricated by a flip-chip technology and flipped to be disposed on the interposer 316 opposite the conductive structures 322. In some embodiments, the dummy dies 30A may be blank dies without any integrated circuit components and/or interconnect structures. In some embodiments, the dummy die 30A may be failed dies including integrated circuit components and/or interconnect structures. When the semiconductor package assembly 500A is in operation, the dummy dies 30A of the dummy die structure 306A do not perform any electrical function, and are not supplied with power. The number of the dummy dies 30A in the same dummy die structure 306A can be adjusted according to the design requirements of the products, and is not limited to the disclosed embodiments.

In some embodiments, the dummy die structure 306A further includes adhesive layers 32 disposed between the dummy dies 30A. In other words, the dummy dies 30A in the same dummy die structure 306A are separated (and electrically isolated) from each other by the adhesive layers 32. The backside surface 30AB of the dummy die 30A farthest from the interposer 316 (the topmost dummy die 30A) and the active surface 30AT of the dummy die 30A closest to the interposer 316 (the bottommost dummy die 30A) are exposed from the adhesive layers 32.

In some embodiments, the dummy dies 30A are thin dies. In some embodiments, in the direction D1, the thickness TA of each of the dummy dies 30A is thinner than the thickness T1 of the first die 302 or the thickness T2 of the second die 304. For example, the thickness T1 of the first die 302 and the thickness T2 of the second die 304 are at least two times the thickness TA.

In the top view as shown in FIG. 1, the dummy dies 30A may fully overlap each other and have the same area (top view area). The backside surface 30AB of the dummy die 30A farthest from the interposer 316 (the topmost dummy die 30A) forms a surface of the dummy die structure 306A farthest from the interposer 316. In some embodiments, the backside surface 302b of the first die 302, the backside surface 304b of the second die 304 and the backside surface 30AB of the dummy die 30A farthest from the interposer 316 (the topmost dummy die 30A) may be flush with each other.

In some embodiments, the dummy dies 30A are made of silicon, copper, aluminum, aluminum oxide (Al₂O₃), ceramic or a combination thereof. In some embodiments, the dummy die 30A closest to the interposer (the bottommost dummy die 30A) of the dummy die structure 306A, the first die 302 and the second die 304 are made of the same material. For example, the dummy die 30A closest to the interposer 316 (the bottommost dummy die 30A), the first die 302 and the second die 304 are made of silicon.

In some embodiments, in the same dummy die structure 306A, all the dummy dies 30A are made of the same material. For example, the dummy die 30A closest to the interposer 316 (the bottommost dummy die 30A) and the remaining dummy dies 30A (other dummy dies 30A disposed on the bottommost dummy die 30A) are made of the same material (e.g., silicon).

In some embodiments, different dummy dies 30A in the same dummy die structure 306A, are made of different material. For example, the dummy die 30A closest to the interposer 316 (the bottommost dummy die 30A) and the remaining dummy dies 30A (other dummy dies 30A disposed on the bottommost dummy die 30A) are made of different materials. For example, the dummy die 30A closest to the interposer 316 (the bottommost dummy die 30A) is made of silicon. The remaining dummy dies 30A (other dummy dies 30A disposed on the bottommost dummy die 30A) are made of materials having a coefficient of thermal expansion (CTE) that is greater than the coefficient of thermal expansion of the dummy die 30A closest to the interposer 316 (the bottommost dummy die 30A) (i.e., the coefficient of thermal expansion of silicon). For example, the remaining dummy dies 30A (other dummy dies 30A disposed on the bottommost dummy die 30A) are made of copper, aluminum, aluminum oxide (Al₂O₃), ceramic or a combination thereof.

In some embodiments, the first die 302 may be mounted on the interposer 316 by conductive structures 303. The second die 304 may be mounted on the interposer 316 by conductive structures 305. In addition, the dummy die structure 306A may be mounted on the interposer 316 by conductive structures 307. As shown in FIG. 2, the conductive structures 307 are disposed directly on the dummy die 30A closest to the interposer 316 (the bottommost dummy die 30A). The conductive structures 307 are disposed directly between the interposer 316 and the dummy die 30A closest to the interposer 316 (the bottommost dummy die 30A). The remaining dummy dies 30A (other dummy dies 30A disposed on the bottommost dummy die 30A) are separated (and electrically isolated) from the conductive structures 307. In other words, there is no conductive structure 307 disposed between and in contact with the remaining dummy dies 30A (other dummy dies 30A disposed on the bottommost dummy die 30A).

In some embodiments, the conductive structures 303, 305 and 307 may include microbumps. In some embodiments, each of the conductive structures 303, 305 and 307 may include an under bump metallurgy (UBM) structure (not shown) and a conductive ball structure (not shown) on the UBM structure. In some embodiments, the conductive structures 303, 305 and 307 may include materials such as nickel, copper, gold, palladium, SnAg solder, or a combination thereof.

In some embodiments, the dummy die 30A closest to the interposer 316 (the bottommost dummy die 30A) may include and adhesion polymer layer 310 on its bonding surface to increase the adhesion ability between the bottommost dummy die and the underfill. The adhesion polymer layer 310 can alleviate or avoid fatigue failure such as underfill delamination at the package corners during temperature cycle testing (TCT) of the semiconductor package assembly 500A.

As shown in FIGS. 1-3, the molding compound 312 is disposed on and in contact with the interposer 316. In addition, the molding compound 312 surrounds and is in contact with the first die 302, the second die 304 and the dummy die structure 306A. The molding compound 312 surrounds and is in contact with the side surfaces of the dummy dies 30A. The backside surface 302b of the first die 302, the backside surface 304b of the second die 304, and the backside surface 30AB of the dummy die 30A farthest from the interposer 316 (the topmost dummy die 30A) may be exposed from the molding compound 312. In some embodiments, the molding compound 312 may be formed of a nonconductive material, such as an epoxy, a resin, a moldable polymer, or the like. The molding compound 312 may be applied while substantially liquid, and then may be cured through a chemical reaction, such as in an epoxy or resin. In some other embodiments, the molding compound 312 may be an ultraviolet (UV) or thermally cured polymer applied as a gel or malleable solid capable of being disposed around the first die 302, the second die 304 and the dummy die structure 306A, and then may be cured using a UV or thermally curing process. The molding compound 312 may be cured with a mold (not shown).

As shown in FIG. 2, the semiconductor package assembly 500 further includes an underfill 315 filling the gap between the first die 302 and the interposer 316, the gap between the second die 304 and the interposer 316, and the gap between the dummy die structure 306A and the interposer 316. The underfill 315 may partially fill the gap between the first die 302 and the second die 304, and the gap between the first die 302 and the dummy die structure 306A. In some embodiments, the conductive structures 303, 305 and 307 are surrounded by the underfill 315. In some embodiments, the underfill 315 surrounds a portion of the first die 302, a portion of the second die 304, a portion of the dummy die structure 306A, and the conductive structures 303, 305 and 307 and is in contact with a portion of the interposer 316 to further reduce the thermal resistance from the first die 302, the second die 304, the dummy die structure 306A to the interposer 316. In addition, the underfill 315 may be disposed to compensate for differing coefficients of thermal expansion (CTEs) between the first die 302, the second die 304, the dummy die structure 306A, the interposer 316, the conductive structures 303, 305 and 307 and the interposer 316.

As shown in FIGS. 1 and 2, the semiconductor package assembly 500 further includes an underfill 250 filling the gap (not shown) between the interposer 316 of the wafer-level fan-out package 300A and the substrate 200. In some embodiments, the underfill 250 surrounds a portion of the molding material 312, the interposer 316 and the conductive structures 322 and is in contact with a portion of the substrate 200 to further reduce the thermal resistance from the fan-out package 300A to the substrate 200. In addition, the underfill 250 may be disposed to compensate for differing coefficients of thermal expansion (CTEs) between the wafer-level fan-out package 300A, the conductive structures 322 and the substrate 200. In some embodiments, the underfill 315 and the underfill 250 may include the same or similar materials.

As shown in FIG. 2, the semiconductor package assembly 500A further includes a stiffener ring 260 mounted on the substrate 200 opposite the conductive structures 222 using an adhesive layer 252. The stiffener ring 260 may be adhered onto the substrate 200 along edges 200E of the substrate 200. The first die 302, the second die 304 and the dummy die structure 306A of the wafer-level fan-out package 300A are surrounded by the stiffener ring 260. The stiffener ring 260 is used for warpage control to reduce the high stress experienced by bonded various materials in the semiconductor package assembly during cycles of heating and cooling. The stiffener ring 260 may provide extra support to the semiconductor package assembly 500A thus reducing warpage. In some embodiments, the stiffener ring 260 are separated from the underfill 250 by a gap (not shown). In some embodiments, edges 260E of the stiffener ring 260 are leveled with the corresponding edges 200E of the substrate 200. Therefore, the edges 260E of the stiffener ring 260 and the edges 200E of the substrate 200 may collectively serve as edges of the semiconductor package assembly 500A. In some embodiments, the stiffener ring 260 includes metals, such as copper.

In the semiconductor package assembly 500A, the dummy die structure 306A is composed of the thinned dummy dies 30A and the adhesive layers 32. Compared with the conventional semiconductor package having block dummy dies at its corners, the dummy die structure 306A may be formed by dividing the conventional block dummy die in the vertical direction (e.g., the direction D1) into thin dummy dies and bonded them together by the adhesive layers 32. Therefore, the coefficient of thermal expansion (CTE) of the dummy die structure 306A can be increased (e.g., greater than the coefficient of thermal expansion (CTE) of silicon) and close to the coefficient of thermal expansion (CTE) of the substrate 200. In addition, the stiffness of the dummy die structure 306A composed of the laminated thinned dummy dies 30A can be further reduced. Compared with the conventional semiconductor package in which the block dummy dies are arranged at the corners of the semiconductor package, the semiconductor package assembly 500A can mitigate the stress and reliability issues.

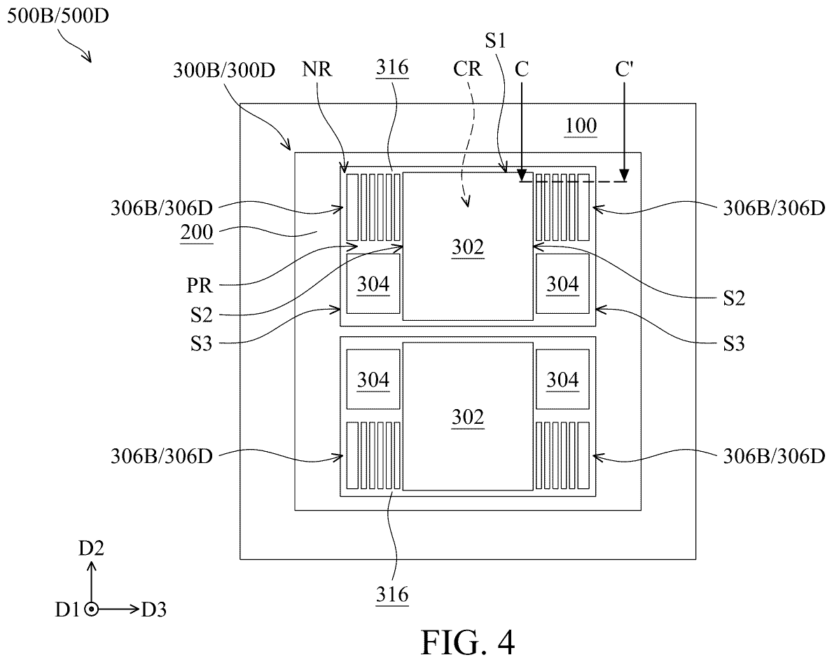

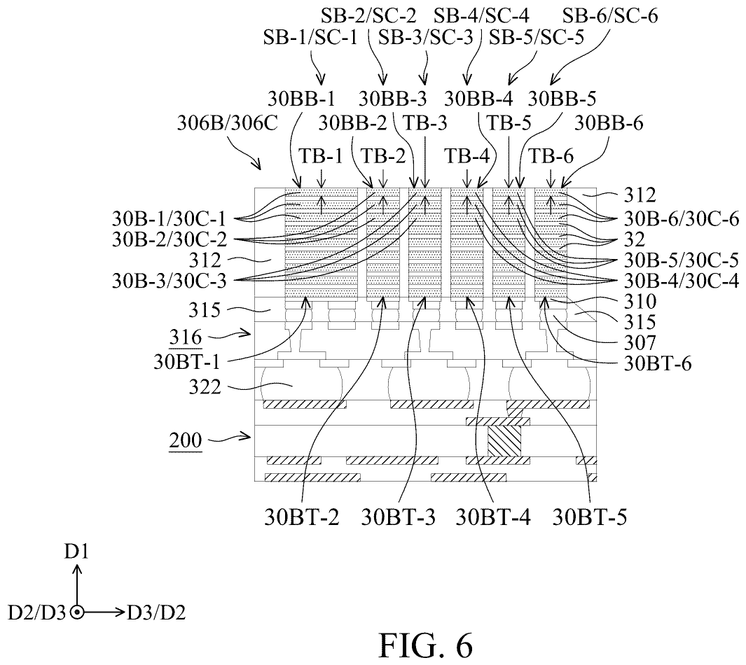

FIG. 4 is a schematic top view of a semiconductor package assembly 500B in accordance with some embodiments of the disclosure, showing the arrangement of dies of the semiconductor package assembly 500B in accordance with some embodiments of the disclosure. FIG. 6 is a cross-sectional view taken along line C-C′ of FIG. 4. Elements of the embodiments hereinafter, that are the same or similar as those previously described with reference to FIGS. 1-3, are not repeated for brevity. For example, the arrangements and structures of the first die 302, the second die 304, the interposer 316 of the fan-out package 300B, and the substrate 200 of the semiconductor package assembly 500B may be the same or similar to the arrangements and structures of the first die 302, the second die 304, the interposer 316 of the fan-out package 300A, and the substrate 200 of the semiconductor package assembly 500A of FIGS. 1-3, and are not repeated for brevity.

As shown in FIGS. 1-4 and 6, the difference between the semiconductor package assembly 500A and the semiconductor package assembly 500B at least includes that a dummy die structure 306B of the fan-out package 300B includes dummy die sub-structures SB-1, SB-2, SB-3, SB-4, SB-5 and SB-6. It is noted that the number of the dummy die sub-structures in the same dummy die structure 306B can be adjusted according to the design requirements of the products, and are not limited to the disclosed embodiments.

As shown in FIGS. 4 and 6, the dummy die sub-structures SB-1, SB-2, SB-3, SB-4, SB-5 and SB-6 extend in a direction D2 (the lateral direction) that is different from the direction D1 (the vertical direction). In addition, the dummy die sub-structures SB-1, SB-2, SB-3, SB-4, SB-5 and SB-6 of the same dummy die structure 306B are separated from each other by the molding compound 312 in a direction D3 (a lateral direction) that is different from the direction D1 (the vertical direction). In this embodiment, the direction D2 is substantially perpendicular to the shorter edge S1 of the first die 302. The direction D3 is substantially parallel to the shorter edge S1 of the first die 302.

In some embodiments, each of the dummy die sub-structures SB-1, SB-2, SB-3, SB-4, SB-5 and SB-6 includes dummy dies stacked on each other in the direction D1. For example, the dummy die sub-structure SB-1 includes dummy dies 30B-1 stacked on each other in the direction D1. The dummy die sub-structure SB-2 includes dummy dies 30B-2 stacked on each other in the direction D1. The dummy die sub-structure SB-3 includes dummy dies 30B-3 stacked on each other in the direction D1. The dummy die sub-structure SB-4 includes dummy dies 30B-4 stacked on each other in the direction D1. The dummy die sub-structure SB-5 includes dummy dies 30B-5 stacked on each other in the direction D1. The dummy die sub-structure SB-6 includes dummy dies 30B-6 stacked on each other in the direction D1. It is noted that the number of the dummy dies in the same dummy die sub-structures SB-1, SB-2, SB-3, SB-4, SB-5 and SB-6 of the dummy die structure 306B can be adjusted according to the design requirements of the products, and are not limited to the disclosed embodiments.

In some embodiments, the dummy dies in the same dummy die sub-structures SB-1, SB-2, SB-3, SB-4, SB-5 and SB-6 are separated from each other by the adhesive layers 32. In the dummy die sub-structures SB-1, SB-2, SB-3, SB-4, SB-5 and SB-6, backside surfaces 30BB-1, 30BB-2, 30BB-3, 30BB-4, 30BB-5 and 30BB-6 of the dummy dies 30B-1, 30B-2, 30B-3, 30B-4, 30B-5 and 30B-6 farthest from the interposer 316 (the topmost dummy die 30B-1, 30B-2, 30B-3, 30B-4, 30B-5 and 30B-6) and active surface 30BT-1, 30BT-2, 30BT-3, 30BT-4, 30BT-5 and 30BT-6 of the dummy dies 30B-1, 30B-2, 30B-3, 30B-4, 30B-5 and 30B-6 closest to the interposer 316 (the bottommost dummy die 30B-1, 30B-2, 30B-3, 30B-4, 30B-5 and 30B-6) are exposed from the adhesive layers 32.

In some embodiments, the dummy dies 30B-1, 30B-2, 30B-3, 30B-4, 30B-5 and 30B-6 are thin dies. In some embodiments, in the direction D1, the thickness TB-1 of each of the dummy dies 30B-1, the thickness TB-2 of each of the dummy dies 30B-2, the thickness TB-3 of each of the dummy dies 30B-3, the thickness TB-4 of each of the dummy dies 30B-4, the thickness TB-5 of each of the dummy dies 30B-5, and the thickness TB-6 of each of the dummy dies 30B-6 are thinner than the thickness T1 of the first die 302 (FIG. 1) or the thickness T2 of the second die 304 (FIG. 1). For example, the thickness T1 of the first die 302 and the thickness T2 of the second die 304 are at least two times any of the thicknesses TB-1, TB-2, TB-3, TB-4, TB-5 and TB-6.

In some embodiments, in the direction D1, the thickness TB-1 of each of the dummy dies 30B-1, the thickness TB-2 of each of the dummy dies 30B-2, the thickness TB-3 of each of the dummy dies 30B-3, the thickness TB-4 of each of the dummy dies 30B-4, the thickness TB-5 of each of the dummy dies 30B-5, and the thickness TB-6 of each of the dummy dies 30B-6 may have the same or different values, according to designs of the products.

In a top view as shown in FIG. 4, the dummy dies in each of the dummy die sub-structures SB-1, SB-2, SB-3, SB-4, SB-5 and SB-6 may fully overlap each other and have the same area (top view area). The total of the top view area of the dummy die sub-structures SB-1, SB-2, SB-3, SB-4, SB-5 and SB-6 of the dummy die structure 306B may be smaller than the total of the top view area of the dummy die structure 306A (FIG. 1). In some embodiments, the dummy die sub-structures SB-1, SB-2, SB-3, SB-4, SB-5 and SB-6 may have the same or different top view areas.

The backside surfaces 30BB-1, 30BB-2, 30BB-3, 30BB-4, 30BB-5 and 30BB-6 of the dummy dies 30B-1, 30B-2, 30B-3, 30B-4, 30B-5 and 30B-6 farthest from the interposer 316 (the topmost dummy die 30B-1, 30B-2, 30B-3, 30B-4, 30B-5 and 30B-6) may belong to a surface of the dummy die structure 306B farthest from the interposer 316 (the top surface of the dummy die structure 306B). In some embodiments, the backside surface 302b of the first die 302, the backside surface 304b of the second die 304 and the backside surfaces 30BB-1, 30BB-2, 30BB-3, 30BB-4, 30BB-5 and 30BB-6 of the dummy dies 30B-1, 30B-2, 30B-3, 30B-4, 30B-5 and 30B-6 farthest from the interposer 316 (the topmost dummy die 30B-1, 30B-2, 30B-3, 30B-4, 30B-5 and 30B-6) may be flush with each other.

Similar to the dummy dies 30A of the dummy die structure 306A, the dummy dies 30B-1, 30B-2, 30B-3, 30B-4, 30B-5 and 30B-6 of the dummy die sub-structures SB-1, SB-2, SB-3, SB-4, SB-5 and SB-6 of the dummy die structure 306B are made of silicon, copper, aluminum, aluminum oxide (Al₂O₃), ceramic or a combination thereof. The dummy dies 30B-1, 30B-2, 30B-3, 30B-4, 30B-5 and 30B-6 closest to the interposer (the bottommost dummy die 30A) of the dummy die sub-structures SB-1, SB-2, SB-3, SB-4, SB-5 and SB-6, the first die 302 and the second die 304 are made of the same material, for example, silicon.

In some embodiments, in the same dummy die sub-structures SB-1, SB-2, SB-3, SB-4, SB-5 and SB-6 of the dummy die structure 306B, all the dummy dies 30B-1, 30B-2, 30B-3, 30B-4, 30B-5 and 30B-6 are made of the same material. For example, in the same dummy die sub-structures SB-1, SB-2, SB-3, SB-4, SB-5 and SB-6 of the dummy die structure 306B, the dummy dies 30B-1, 30B-2, 30B-3, 30B-4, 30B-5 and 30B-6 closest to the interposer 316 (the bottommost dummy dies 30B-1, 30B-2, 30B-3, 30B-4, 30B-5 and 30B-6) and the remaining dummy dies 30B-1, 30B-2, 30B-3, 30B-4, 30B-5 and 30B-6 (other dummy dies 30B-1, 30B-2, 30B-3, 30B-4, 30B-5 and 30B-6A disposed on the bottommost dummy dies 30B-1, 30B-2, 30B-3, 30B-4, 30B-5 and 30B-6) are made of the same material, for example, silicon.

In some embodiments, different dummy dies 30B-1, 30B-2, 30B-3, 30B-4, 30B-5 and 30B-6 in the same dummy die sub-structures SB-1, SB-2, SB-3, SB-4, SB-5 and SB-6 of the dummy die structure 306B, are made of different material. For example, in the same dummy die sub-structures SB-1, SB-2, SB-3, SB-4, SB-5 and SB-6 of the dummy die structure 306B, the dummy dies 30B-1, 30B-2, 30B-3, 30B-4, 30B-5 and 30B-6 closest to the interposer 316 (the bottommost dummy dies 30B-1, 30B-2, 30B-3, 30B-4, 30B-5 and 30B-6) and the remaining dummy dies 30B-1, 30B-2, 30B-3, 30B-4, 30B-5 and 30B-6 (other dummy dies 30B-1, 30B-2, 30B-3, 30B-4, 30B-5 and 30B-6 disposed on the bottommost dummy dies 30B-1, 30B-2, 30B-3, 30B-4, 30B-5 and 30B-6) are made of different materials. For example, the dummy dies 30B-1, 30B-2, 30B-3, 30B-4, 30B-5 and 30B-6 closest to the interposer 316 (the bottommost dummy dies 30B-1, 30B-2, 30B-3, 30B-4, 30B-5 and 30B-6) is made of silicon. The remaining dummy dies 30B-1, 30B-2, 30B-3, 30B-4, 30B-5 and 30B-6 (other dummy dies 30B-1, 30B-2, 30B-3, 30B-4, 30B-5 and 30B-6 disposed on the bottommost dummy dies 30B-1, 30B-2, 30B-3, 30B-4, 30B-5 and 30B-6) are made of materials having a coefficient of thermal expansion (CTE) that is greater than the coefficient of thermal expansion of the dummy dies 30B-1, 30B-2, 30B-3, 30B-4, 30B-5 and 30B-6 closest to the interposer 316 (the bottommost dummy dies 30B-1, 30B-2, 30B-3, 30B-4, 30B-5 and 30B-6) (i.e., the coefficient of thermal expansion of silicon). For example, the remaining dummy dies 30B-1, 30B-2, 30B-3, 30B-4, 30B-5 and 30B-6 (other dummy dies 30B-1, 30B-2, 30B-3, 30B-4, 30B-5 and 30B-6 disposed on the bottommost dummy dies 30B-1, 30B-2, 30B-3, 30B-4, 30B-5 and 30B-6) are made of copper, aluminum, aluminum oxide (Al₂O₃), ceramic or a combination thereof.

In the semiconductor package assembly 500B, the dummy die structure 306B is composed of the dummy die sub-structures SB-1, SB-2, SB-3, SB-4, SB-5 and SB-6 and the molding compound 312 between them. In addition, each of the dummy die sub-structures SB-1, SB-2, SB-3, SB-4, SB-5 and SB-6 is composed of the thinned dummy dies (e.g., the dummy dies 30B-1, 30B-2, 30B-3, 30B-4, 30B-5 and 30B-6) and the adhesive layers 32 between them. Compared with the conventional semiconductor package that places one block dummy die at one corner of the semiconductor package, the dummy die structure 306B may be formed by dividing the single block dummy die into thin and small dummy dies in the vertical direction (e.g., the direction D1) and the lateral direction (e.g., the direction D3). The total top view area of the dummy dies of the dummy die structure 306B (FIG. 4) may be smaller than the total top view area of the dummy die structure 306A (FIG. 1). Therefore, the coefficient of thermal expansion (CTE) of the dummy die structure 306B can be further increased (e.g., greater than the coefficient of thermal expansion (CTE) of silicon) and close to the coefficient of thermal expansion (CTE) of the substrate 200. In addition, the stiffness of the dummy die structure 306B composed of the dummy die sub-structures SB-1, SB-2, SB-3, SB-4, SB-5 and SB-6 including the laminated thinned dummy dies 30B-1, 30B-2, 30B-3, 30B-4, 30B-5 and 30B-6 can be further reduced. Compared with the conventional semiconductor package in which the block dummy dies are arranged at the corners of the semiconductor package, the semiconductor package assembly 500B can further mitigate the stress and reliability issues.

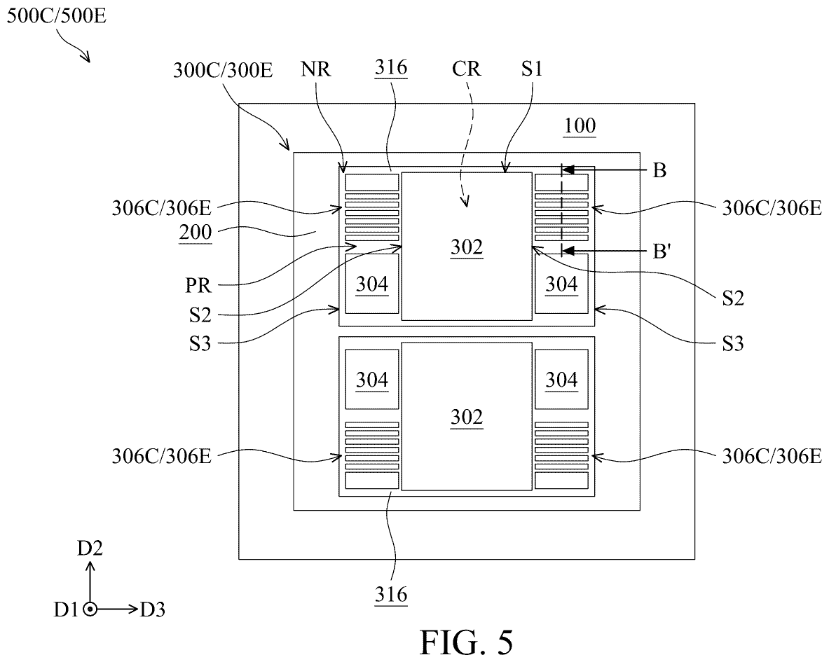

FIG. 5 is a schematic top view of a semiconductor package assembly 500C in accordance with some embodiments of the disclosure, showing the arrangement of dies of the semiconductor package assembly 500C in accordance with some embodiments of the disclosure. FIG. 6 is also a cross-sectional view taken along line B-B′ of FIG. 5. Elements of the embodiments hereinafter, that are the same or similar as those previously described with reference to FIGS. 1 to 3, are not repeated for brevity. For example, the arrangements and structures of the first die 302, the second die 304, the interposer 316 of the fan-out package 300C, and the substrate 200 of the semiconductor package assembly 500C may be the same or similar to the arrangements and structures of the first die 302, the second die 304, the interposer 316 of the fan-out package 300A, and the substrate 200 of the semiconductor package assembly 500A of FIGS. 1-3, and are not repeated for brevity.

As shown in FIGS. 4-6, the difference between the semiconductor package assembly 500B and the semiconductor package assembly 500C at least includes that a dummy die structure 306C of the fan-out package 300C includes dummy die sub-structures SC-1, SC-2, SC-3, SC-4, SC-5 and SC-6 extend in the direction D3 and separated from each other by the molding compound 312 in the direction D2. It is noted that the number of the dummy die sub-structures in the same dummy die structure 306C can be adjusted according to the design requirements of the products, and are not limited to the disclosed embodiments.

In some embodiments, each of the dummy die sub-structures SC-1, SC-2, SC-3, SC-4, SC-5 and SC-6 includes dummy dies stacked on each other in the direction D1. For example, the dummy die sub-structure SC-1 includes dummy dies 30C-1 stacked on each other in the direction D1. The dummy die sub-structure SC-2 includes dummy dies 30C-2 stacked on each other in the direction D1. The dummy die sub-structure SC-3 includes dummy dies 30C-3 stacked on each other in the direction D1. The dummy die sub-structure SC-4 includes dummy dies 30C-4 stacked on each other in the direction D1. The dummy die sub-structure SC-5 includes dummy dies 30C-5 stacked on each other in the direction D1. The dummy die sub-structure SC-6 includes dummy dies 30C-6 stacked on each other in the direction D1. It is noted that the number of the dummy dies in the same dummy die sub-structures SC-1, SC-2, SC-3, SC-4, SC-5 and SC-6 of the dummy die structure 306C can be adjusted according to the design requirements of the products, and are not limited to the disclosed embodiments.

In some embodiments, the structure, arrangement and materials of the dummy die structure 306C may have similar to those of the dummy die structure 306B. In the top view as shown in FIG. 4, the dummy die structure 306C may be formed by rotating the dummy die structure 306B by 90 degrees in the clockwise or anticlockwise direction about the axis in the direction D1.

In the semiconductor package assembly 500C, the dummy die structure 306C is composed of the dummy die sub-structures SC-1, SC-2, SC-3, SC-4, SC-5 and SC-6 and the molding compound 312 between them. In addition, each of the dummy die sub-structures SC-1, SC-2, SC-3, SC-4, SC-5 and SC-6 is composed of the thinned dummy dies (e.g., the dummy dies 30C-1, 30C-2, 30C-3, 30C-4, 30C-5 and 30C-6) and the adhesive layers 32 between them. Compared with the conventional semiconductor package that places one block dummy die at one corner of the semiconductor package, the dummy die structure 306C may be formed by dividing the conventional block dummy die into thin and small dummy dies in the vertical direction (the direction D1) and the lateral direction (the direction D3). The total top view area of the dummy dies of the dummy die structure 306C (FIG. 5) may be smaller than the total top view area of the dummy die structure 306A (FIG. 1). Therefore, the coefficient of thermal expansion (CTE) of the dummy die structure 306C can be further increased (e.g., greater than the coefficient of thermal expansion (CTE) of silicon) and close to the coefficient of thermal expansion (CTE) of the substrate 200. In addition, the stiffness of the dummy die structure 306C composed of the dummy die sub-structures SC-1, SC-2, SC-3, SC-4, SC-5 and SC-6 including the laminated thinned dummy dies 30C-1, 30C-2, 30C-3, 30C-4, 30C-5 and 30C-6 can be further reduced. Compared with the conventional semiconductor package in which the block dummy dies are arranged at the corners of the semiconductor package, the semiconductor package assembly 500C can further mitigate the stress and reliability issues.

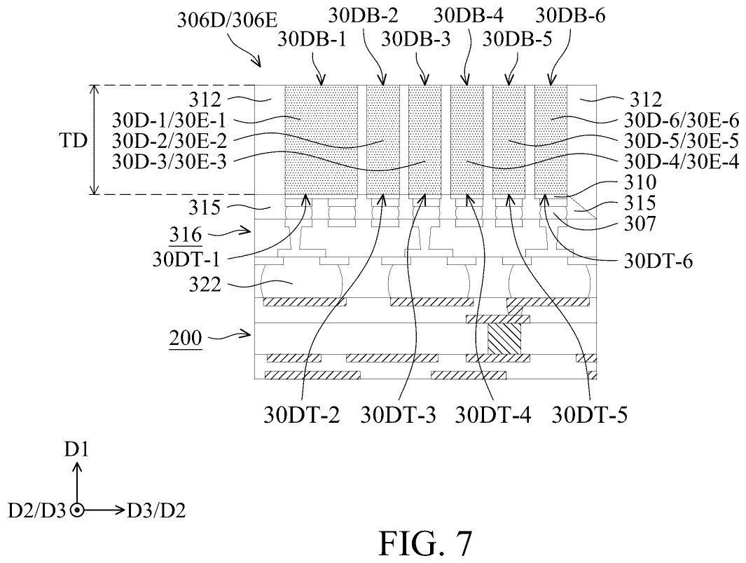

FIG. 4 is also a schematic top view of a semiconductor package assembly 500D in accordance with some embodiments of the disclosure, showing the arrangement of dies of the semiconductor package assembly 500D in accordance with some embodiments of the disclosure. FIG. 7 is a cross-sectional view taken along line C-C′ of FIG. 4. Elements of the embodiments hereinafter, that are the same or similar as those previously described with reference to FIGS. 1-3 and 6, are not repeated for brevity. For example, the arrangements and structures of the first die 302, the second die 304, the interposer 316 of the fan-out package 300D, and the substrate 200 of the semiconductor package assembly 500D may be the same or similar to the arrangements and structures of the first die 302, the second die 304, the interposer 316 of the fan-out package 300A, and the substrate 200 of the semiconductor package assembly 500A of FIGS. 1-3, and are not repeated for brevity.

As shown in FIGS. 4 and 7, the difference between the semiconductor package assembly 500A and the semiconductor package assembly 500D at least includes that a dummy die structure 306D of the fan-out package 300D includes dummy dies 30D-1, 30D-2, 30D-3, 30D-4, 30D-5 and 30D-6 extend in the direction D2 and separated from the first die 302 by the molding compound 312 in the direction D3 (the lateral direction). It is noted that the number of the dummy dies 30D-1, 30D-2, 30D-3, 30D-4, 30D-5 and 30D-6 in the same dummy die structure 306D can be adjusted according to the design requirements of the products, and are not limited to the disclosed embodiments.

As shown in FIGS. 4 and 7, the dummy dies 30D-1, 30D-2, 30D-3, 30D-4, 30D-5 and 30D-6 extend in the direction D2 (the lateral direction) that that is different from the direction D1 (the vertical direction). In addition, the dummy dies 30D-1, 30D-2, 30D-3, 30D-4, 30D-5 and 30D-6 of the same dummy die structure 306D are separated from each other by the molding compound 312 in the direction D3 (a lateral direction) that is different from the direction D1 (the vertical direction) and the direction D2 (another lateral direction).

In some embodiments, in the direction D1, the dummy dies 30D-1, 30D-2, 30D-3, 30D-4, 30D-5 and 30D-6 may have the same thickness TD. The thickness TD of the dummy dies 30D-1, 30D-2, 30D-3, 30D-4, 30D-5 and 30D-6 may be equal to the thickness T1 of the first die 302 (FIG. 1) or the thickness T2 of the second die 304 (FIG. 1).

As shown in FIG. 7, the dummy die 30D-1 has an active surface 30DT-1 and a backside surface 30DB-1. The backside surface 30DB-1 is opposite the active surface 30DT-1. The dummy die 30D-2 has an active surface 30DT-2 and a backside surface 30DB-2. The backside surface 30DB-2 is opposite the active surface 30DT-2. The dummy die 30D-3 has an active surface 30DT-3 and a backside surface 30DB-3. The backside surface 30DB-3 is opposite the active surface 30DT-3. The dummy die 30D-4 has an active surface 30DT-4 and a backside surface 30DB-4. The backside surface 30DB-4 is opposite the active surface 30DT-4. The dummy die 30D-5 has an active surface 30DT-5 and a backside surface 30DB-5. The backside surface 30DB-5 is opposite the active surface 30DT-5. The dummy die 30D-6 has an active surface 30DT-6 and a backside surface 30DB-6. The backside surface 30DB-6 is opposite the active surface 30DT-6.

In some embodiments, the dummy dies 30D-1, 30D-2, 30D-3, 30D-4, 30D-5 may have the same or different top view areas. In other words, in the top view as shown in FIG. 4, the backside surfaces 30DB-1, 30DB-2, 30DB-3, 30DB-4, 30DB-5 and 30DB-6 of the dummy dies 30D-1, 30D-2, 30D-3, 30D-4, 30D-5 and 30D-6 may have the same or different areas.

The backside surfaces 30DB-1, 30DB-2, 30DB-3, 30DB-4, 30DB-5 and 30DB-6 of the dummy dies 30D-1, 30D-2, 30D-3, 30D-4, 30D-5 and 30D-6 may belong to a surface of the dummy die structure 306D farthest from the interposer 316 (i.e., the top surface of the dummy die structure 306D). In some embodiments, the backside surface 302b of the first die 302 (FIG. 1), the backside surface 304b of the second die 304 (FIG. 1), the backside surface 30DB-1 of the dummy die 30D-1, the backside surface 30DB-2 of the dummy die 30D-2, the backside surface 30DB-3 of the dummy die 30D-3, the backside surface 30DB-4 of the dummy die 30D-4, the backside surface 30DB-5 of the dummy die 30D-5, the backside surface 30DB-6 of the dummy die 30D-6 may flush with each other.

In some embodiments, the dummy dies 30D-1, 30D-2, 30D-3, 30D-4, 30D-5 and 30D-6 are made of silicon. Alternatively, the dummy dies 30D-1, 30D-2, 30D-3, 30D-4, 30D-5 and 30D-6 are made of copper, aluminum, aluminum oxide (Al₂O₃), ceramic or a combination thereof. For example, the dummy dies 30D-1, 30D-2, 30D-3, 30D-4, 30D-5 and 30D-6, the first die 302 and the second die 304 are made of silicon.

In some embodiments, the conductive structures 307 are disposed directly on the active surface 30DT-1 of the dummy die 30D-1, the active surface 30DT-2 of the dummy die 30D-2, the active surface 30DT-3 of the dummy die 30D-3, the active surface 30DT-4 of the dummy die 30D-4, the active surface 30DT-5 of the dummy die 30D-5, and the active surface 30DT-6 of the dummy die 30D-6.

In the semiconductor package assembly 500D, the dummy die structure 306D is composed of the block dummy dies 30D-1, 30D-2, 30D-3, 30D-4, 30D-5 and 30D-6 and the and the molding compound 312 between them. Compared with the conventional semiconductor package that places one block dummy die at one corner of the semiconductor package, the dummy die structure 306D may be formed by dividing one conventional block dummy die into multiple block dummy dies having smaller top view area (e.g., the smaller backside surfaces 30DB-1, 30DB-2, 30DB-3, 30DB-4, 30DB-5 and 30DB-6). Therefore, the coefficient of thermal expansion (CTE) of the dummy die structure 306D can be increased (e.g., greater than the coefficient of thermal expansion (CTE) of silicon) and close to the coefficient of thermal expansion (CTE) of the substrate 200. In addition, the stiffness of the dummy die structure 306D composed of the smaller dummy dies 30D-1, 30D-2, 30D-3, 30D-4, 30D-5 and 30D-6 can be further reduced. Compared with the conventional semiconductor package, the semiconductor package assembly 500D can mitigate the stress and reliability issues.

FIG. 5 is also a schematic top view of a semiconductor package assembly 500E in accordance with some embodiments of the disclosure, showing the arrangement of dies of the semiconductor package assembly 500E in accordance with some embodiments of the disclosure. FIG. 7 is also a cross-sectional view taken along line B-B′ of FIG. 5. Elements of the embodiments hereinafter, that are the same or similar as those previously described with reference to FIGS. 1-4 and 6, are not repeated for brevity. For example, the arrangements and structures of the first die 302, the second die 304, the interposer 316 of the fan-out package 300E, and the substrate 200 of the semiconductor package assembly 500E may be the same or similar to the arrangements and structures of the first die 302, the second die 304, the interposer 316 of the fan-out package 300A, and the substrate 200 of the semiconductor package assembly 500A of FIGS. 1-3, and are not repeated for brevity.

As shown in FIGS. 4, 5 to 7, the difference between the semiconductor package assembly 500D and the semiconductor package assembly 500E at least includes that a dummy die structure 306E of a fan-out package 300E includes dummy dies 30E-1, 30E-2, 30E-3, 30E-4, 30E-5 and 30E-6 extend in the direction D3 and separated from each other by the molding compound 312 in the direction D2. It is noted that the number of the dummy dies in the same dummy die structure 306E can be adjusted according to the design requirements of the products, and are not limited to the disclosed embodiments.

In some embodiments, the structure, arrangement and materials of the dummy die structure 306E may have similar to those of the dummy die structure 306D. In the top view as shown in FIG. 5, the dummy die structure 306E may be formed by rotating the dummy die structure 306D by 90 degrees in the clockwise or anticlockwise direction about the axis in the direction D1.

In the semiconductor package assembly 500E, the dummy die structure 306E is composed of the block dummy dies 30E-1, 30E-2, 30E-3, 30E-4, 30E-5 and 30E-6 and the and the molding compound 312 between them. Compared with the conventional semiconductor package that places one block dummy die at one corner of the semiconductor package, the dummy die structure 306E may be formed by dividing one conventional block dummy die into multiple block dummy dies having smaller top view area (and size). Therefore, the coefficient of thermal expansion (CTE) of the dummy die structure 306E can be increased (e.g., greater than the coefficient of thermal expansion (CTE) of silicon) and close to the coefficient of thermal expansion (CTE) of the substrate 200. In addition, the stiffness of the dummy die structure 306E composed of the smaller dummy dies 30E-1, 30E-2, 30E-3, 30E-4, 30E-5 and 30E-6 can be further reduced. Compared with the conventional semiconductor package, the semiconductor package assembly 500E can mitigate the stress and reliability issues.

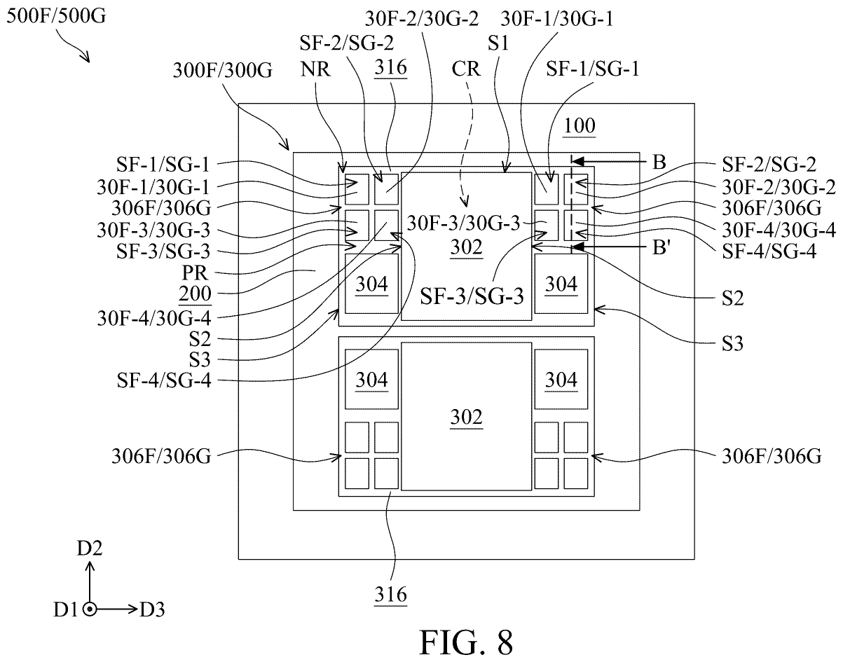

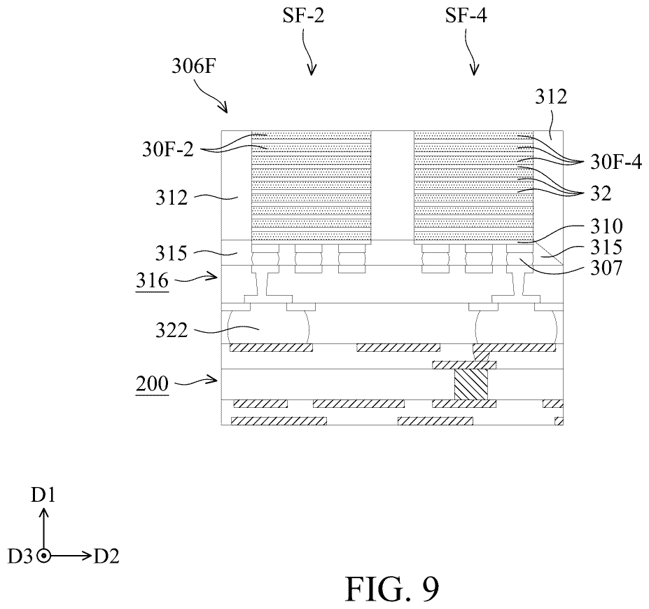

FIG. 8 is a schematic top view of a semiconductor package assembly 500F in accordance with some embodiments of the disclosure, showing the arrangement of dies of the semiconductor package assembly 500F in accordance with some embodiments of the disclosure. FIG. 9 is a cross-sectional view taken along line B-B′ of FIG. 8. Elements of the embodiments hereinafter, that are the same or similar as those previously described with reference to FIGS. 1 to 7, are not repeated for brevity. For example, the arrangements and structures of the first die 302, the second die 304, the interposer 316 of the fan-out package 300F, and the substrate 200 of the semiconductor package assembly 500F may be the same or similar to the arrangements and structures of the first die 302, the second die 304, the interposer 316 of the fan-out package 300A, and the substrate 200 of the semiconductor package assembly 500A of FIGS. 1-3, and are not repeated for brevity.

As shown in FIGS. 4-6, 8 and 9, the difference between the semiconductor package assembly 500B (or the semiconductor package assembly 500C) and the semiconductor package assembly 500F at least includes that a dummy die structure 306F of the fan-out package 300F includes dummy die sub-structures SF-1, SF-2, SF-3 and SF-4 separated from each other by the molding compound 312 in the directions D2 and D3 (in two lateral directions) that are different from the direction D1 (the vertical direction). It is noted that the number of the dummy die sub-structures in the same dummy die structure 306F can be adjusted according to the design requirements of the products, and are not limited to the disclosed embodiments.

In some embodiments, each of the dummy die sub-structures SF-1, SF-2, SF-3 and SF-4 includes dummy dies stacked on each other in the direction D1. For example, the dummy die sub-structure SF-1 includes dummy dies 30F-1 stacked on each other in the direction D1. The dummy die sub-structure SF-2 includes dummy dies 30F-2 stacked on each other in the direction D1. The dummy die sub-structure SF-3 includes dummy dies 30F-3 stacked on each other in the direction D1. The dummy die sub-structure SF-4 includes dummy dies 30F-4 stacked on each other in the direction D1. It is noted that the number of the dummy dies in the same dummy die sub-structures SF-1, SF-2, SF-3 and SF-4 of the dummy die structure 306F can be adjusted according to the design requirements of the products, and are not limited to the disclosed embodiments.

In a top view as shown in FIG. 8, the dummy dies in each of the dummy die sub-structures SF-1, SF-2, SF-3 and SF-4 may fully overlap each other and have the same area (top view area). The total of the top view area of the dummy die sub-structures SF-1, SF-2, SF-3 and SF-4 of the dummy die structure 306F may be smaller than the total of the top view area of the dummy die structures 306A, 306B and 306C as shown in FIGS. 1, 4 and 5. In some embodiments, the dummy die sub-structures SF-1, SF-2, SF-3 and SF-4 may have the same or different top view areas.

In some embodiments, the structure, arrangement and materials of the dummy die structure 306F may have similar to those of the dummy die structures 306B and 306C but have different top view shapes (and top view areas). In the top view as shown in FIG. 8, the dummy die sub-structures of the dummy die structure 306F may be formed by further dividing the dummy die sub-structure of the dummy die structures 306B (FIG. 4) in the direction D3 (or the dummy die sub-structure of the dummy die structures 306C (FIG. 5) in the direction D2) into smaller dummy die sub-structures. For example, the dummy die sub-structures of the dummy die structure 306E may be formed by arranging square dummy die sub-structures SF-1, SF-2, SF-3 and SF-4 in 2×2 array. It is noted that the dummy die sub-structures of the dummy die structure 306F may have other rectangular shaped die arrangements and is not limited to the disclosure.

In the semiconductor package assembly 500F, the dummy die structure 306F is composed of the dummy die sub-structures SF-1, SF-2, SF-3 and SF-4 and the molding compound 312 between them. In addition, each of the dummy die sub-structures SF-1, SF-2, SF-3 and SF-4 is composed of the thinned dummy dies (e.g., the dummy dies 30F-1, 30F-2, 30F-3 and 30F-4) and the adhesive layers 32 between them. Compared with the conventional semiconductor package that places one block dummy dies at one corner of the semiconductor package, the dummy die structure 306F may be formed by dividing a single block dummy die along the vertical direction (the direction D1) and two different lateral direction (the directions D2 and D3) into small dummy die sub-structures SF-1, SF-2, SF-3 and SF-4 composed of thin dummy dies. The total top view area of the dummy die structure 306F (FIG. 8) may be smaller than the total top view area of the dummy die structures 306C and 306D (FIGS. 4 and 5), and much smaller than the total top view area of the dummy die structure 306A (FIG. 1). Therefore, the coefficient of thermal expansion (CTE) of the dummy die structure 306F can be further increased (e.g., greater than the coefficient of thermal expansion (CTE) of silicon) and close to the coefficient of thermal expansion (CTE) of the substrate 200. In addition, the stiffness of the dummy die structure 306F composed of the dummy die sub-structures SF-1, SF-2, SF-3 and SF-4 including the laminated thinned dummy dies 30F-1, 30F-2, 30F-3 and 30F-4 can be further reduced. Compared with the conventional semiconductor package in which the block dummy dies are arranged at the corners of the semiconductor package, the semiconductor package assembly 500F can further mitigate the stress and reliability issues.

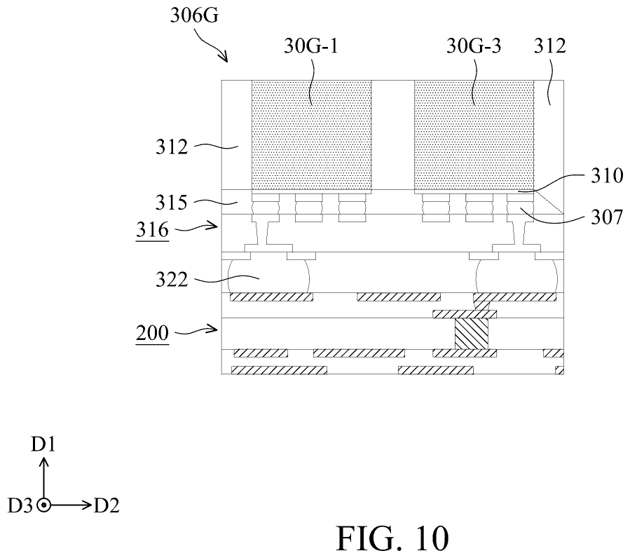

FIG. 8 is also a schematic top view of a semiconductor package assembly 500G in accordance with some embodiments of the disclosure, showing the arrangement of dies of the semiconductor package assembly 500G in accordance with some embodiments of the disclosure. FIG. 10 is a cross-sectional view taken along line B-B′ of FIG. 8. Elements of the embodiments hereinafter, that are the same or similar as those previously described with reference to FIGS. 1 to 6, are not repeated for brevity. For example, the arrangements and structures of the first die 302, the second die 304, the interposer 316 of the fan-out package 300G, and the substrate 200 of the semiconductor package assembly 500G may be the same or similar to the arrangements and structures of the first die 302, the second die 304, the interposer 316 of the fan-out package 300A, and the substrate 200 of the semiconductor package assembly 500A of FIGS. 1-3, and are not repeated for brevity.

As shown in FIGS. 4, 5, 7, 8 and 10, the difference between the semiconductor package assembly 500D (or the semiconductor package assembly 500E) and the semiconductor package assembly 500G at least includes that a dummy die structure 306G of the fan-out package 300G includes dummy dies 30G-1, 30G-2, 30G-3 and 30G-4 separated from each other by the molding compound 312 in the directions D2 and D3 (in two lateral directions) that are different from the direction D1 (the vertical direction). It is noted that the number of the dummy dies in the same dummy die structure 306G can be adjusted according to the design requirements of the products, and are not limited to the disclosed embodiments.

In a top view as shown in FIG. 8, the total of the top view area of the dummy dies 30G-1, 30G-2, 30G-3 and 30G-4 of the dummy die structure 306G may be smaller than the total of the top view area of the dummy die structures 306D and 306E as shown in FIGS. 4 and 5. In some embodiments, the dummy dies 30G-1, 30G-2, 30G-3 and 30G-4 may have the same or different top view areas.

In some embodiments, the structure, arrangement and materials of the dummy die structure 306G may have similar to those of the dummy die structures 306D and 306E but have different top view shapes (and top view areas). In the top view as shown in FIG. 8, the dummy die sub-structures of the dummy die structure 306G may be formed by further dividing the dummy dies of the dummy die structure 306D (FIG. 4) in the direction D3 (or the dummy dies of the dummy die structure 306E (FIG. 5) in the direction D2) into smaller dummy dies. For example, the dummy dies of the dummy die structure 306F may be formed by arranging square dummy dies 30G-1, 30G-2, 30G-3 and 30G-4 in 2×2 array. It is noted that the dummy die sub-structures of the dummy die structure 306G may have other rectangular shaped die arrangements and is not limited to the disclosure.

In the semiconductor package assembly 500G, the dummy die structure 306G is composed of the block dummy dies 30G-1, 30G-2, 30G-3 and 30G-4 and the and the molding compound 312 between them. Compared with the conventional semiconductor package that places one block dummy die at one corner of the semiconductor package, the dummy die structure 306G may be formed by dividing one conventional block dummy die into multiple block dummy dies having smaller top view area (and size). The total top view area of the dummy dies of the dummy die structure 306G (FIG. 8) may be smaller than the total top view area of the dummy die structures 306D and 306E (FIGS. 4 and 5). Therefore, the coefficient of thermal expansion (CTE) of the dummy die structure 306F can be increased (e.g., greater than the coefficient of thermal expansion (CTE) of silicon) and close to the coefficient of thermal expansion (CTE) of the substrate 200. In addition, the stiffness of the dummy die structure 306F composed of the smaller dummy dies 30G-1, 30G-2, 30G-3 and 30G-4 can be further reduced. Compared with the conventional semiconductor package, the semiconductor package assembly 500G can mitigate the stress and reliability issues.

Embodiments provide a semiconductor package assembly. The semiconductor package assembly includes a substrate, an interposer, a first die, a second die, and a dummy die structure. The interposer is disposed on the substrate. The interposer includes a central region and a peripheral region. The peripheral region further includes a corner region and a non-corner region. The first die is disposed on the interposer in the central region. The second die is disposed beside the first die and is located in the non-corner region of the peripheral region of the interposer. The dummy die structure is disposed beside the first die and the second die and is located in the corner region of the peripheral region of the interposer. The dummy die structure includes dummy dies stacked on each other in a first direction.

In some embodiments, the second die and the dummy die structure are disposed adjacent to a first edge of the first die and located between the first edge of the first die and a second edge of the interposer.

In some embodiments, in the first direction, the thickness of each of the dummy dies is thinner than the thickness of the first die or the thickness of the second die.

In some embodiments, the dummy die structure further comprises adhesive layers disposed between the dummy dies.

In some embodiments, the dummy dies fully overlap each other in the first direction.

In some embodiments, the backside surface of the dummy die farthest from the interposer forms the top surface of the dummy die structure.

In some embodiments, the dummy die closest to the interposer, the first die and the second die are made of the same material.

In some embodiments, the dummy dies of the dummy die structure are made of different materials.

In some embodiments, the coefficient of thermal expansion (CTE) of the remaining dummy dies is greater than the coefficient of thermal expansion of the dummy die closest to the interposer.

In some embodiments, the dummy die closest to the interposer and the remaining dummy dies are made of different materials.

In some embodiments, all the dummy dies of the dummy die structure are made of the same material.

In some embodiments, the semiconductor package further includes conductive structures disposed between the interposer and the dummy die closest to the interposer, and the remaining dummy dies are separated from the conductive structures.

In some embodiments, backside surfaces of the first die, the second die, and a dummy die of the dummy die structure farthest from the interposer are flush with each other.

In some embodiments, the dummy dies are separated from the first die or the second die in the first direction, and the dummy dies, the first die and the second die have the same thickness in a second direction that is different from the first direction.

In some embodiments, the first direction is a lateral direction, and the second direction is a vertical direction.

In some embodiments, each of the dummy dies has a different area in the second direction.

In some embodiments, the dummy die structure comprises dummy die sub-structures separated from each other in a second direction that that is different from the first direction.

In some embodiments, the first direction is a vertical direction, and the second direction is a lateral direction.

In some embodiments, the dummy die sub-structures are further separated from each other in a third direction that is different from the first direction and the second direction.

In some embodiments, the semiconductor package further includes an underfill and a molding compound. The underfill fills the gap between the first die and the interposer, the gap between the second die and the interposer, and the gap between the dummy die structure and the interposer. The molding compound surrounds the first die, the second die, and the dummy die structure. The molding compound is in contact with the interposer.

In the semiconductor package assembly, the dummy die structure is formed by dividing a single block dummy die in the lateral direction and/or the vertical direction into multiple dummy dies or dummy die sub structures composed of multiple dummy dies. Compared with the conventional semiconductor package placing one block dummy die in one corner of the semiconductor package, the semiconductor package assembly places the dummy die structure multiple having dummy dies in the same corner of the fan-out package (e.g., the fan-out packages 300A-300G). Therefore, the coefficient of thermal expansion (CTE) of the dummy die structure can be increased (e.g., greater than the coefficient of thermal expansion (CTE) of silicon) and close to the coefficient of thermal expansion (CTE) of the substrate (e.g., the substrate 200). In addition, the stiffness of the dummy die structure composed of the smaller dummy dies (or dummy die sub structures composed of smaller and thinner dummy dies) can be further reduced. Compared with the conventional semiconductor package, the semiconductor package assembly can mitigate the stress and reliability issues.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package assembly, comprising:
a substrate;
an interposer disposed on the substrate, wherein the interposer comprises a central region and a peripheral region, wherein the peripheral region comprises a corner region and a non-corner region;
a first die disposed on the interposer in the central region;
a second die disposed beside the first die and located in the non-corner region of the peripheral region of the interposer; and
a dummy die structure disposed beside the first die and the second die, and located in the corner region of the peripheral region of the interposer, wherein the dummy die structure comprises dummy dies stacked on each other in a first direction.

2. The semiconductor package assembly as claimed in claim 1, wherein the second die and the dummy die structure are disposed adjacent to a first edge of the first die and located between the first edge of the first die and a second edge of the interposer 3. The semiconductor package assembly as claimed in claim 1, wherein in the first direction, a thickness of each of the dummy dies is thinner than a thickness of the first die or a thickness of the second die.

4. The semiconductor package assembly as claimed in claim 1, wherein the dummy die structure further comprises adhesive layers disposed between the dummy dies.

5. The semiconductor package assembly as claimed in claim 1, wherein the dummy dies are fully overlapped with each other in the first direction.

6. The semiconductor package assembly as claimed in claim 1, wherein a backside surface of the dummy die farthest from the interposer forms a top surface of the dummy die structure.

7. The semiconductor package assembly as claimed in claim 1, wherein the dummy die closest to the interposer, the first die, and the second die are made of the same material.

8. The semiconductor package assembly as claimed in claim 1, wherein the dummy dies of the dummy die structure are made of different materials.

9. The semiconductor package assembly as claimed in claim 8, wherein a coefficient of thermal expansion (CTE) of the remaining dummy dies is greater than a coefficient of thermal expansion of the dummy die closest to the interposer.

10. The semiconductor package assembly as claimed in claim 8, wherein the dummy die closest to the interposer and the remaining dummy dies are made of different materials.

11. The semiconductor package assembly as claimed in claim 1, wherein all the dummy dies of the dummy die structure are made of a same material.

12. The semiconductor package assembly as claimed in claim 1, further comprising:
conductive structures disposed between the interposer and the dummy die closest to the interposer, and the remaining dummy dies are separated from the conductive structures.

13. The semiconductor package assembly as claimed in claim 1, wherein backside surfaces of the first die, the second die, and a dummy die of the dummy die structure farthest from the interposer are flush with each other.

14. The semiconductor package assembly as claimed in claim 1, wherein the dummy dies are separated from the first die or the second die in the first direction, and the dummy dies, the first die and the second die have the same thickness in a second direction that is different from the first direction.

15. The semiconductor package assembly as claimed in claim 14, wherein the first direction is a lateral direction, and the second direction is a vertical direction.

16. The semiconductor package assembly as claimed in claim 14, wherein each of the dummy dies has a different area in the second direction.

17. The semiconductor package assembly as claimed in claim 1, wherein the dummy die structure comprises dummy die sub-structures separated from each other in a second direction that is different from the first direction.

18. The semiconductor package assembly as claimed in claim 17, wherein the first direction is a vertical direction, and the second direction is a lateral direction.

19. The semiconductor package assembly as claimed in claim 17, wherein the dummy die sub-structures are further separated from each other in a third direction that is different from the first direction and the second direction.

20. The semiconductor package assembly as claimed in claim 1, further comprising:
an underfill filling a gap between the first die and the interposer, a gap between the second die and the interposer, a gap between the dummy die structure and the interposer; and
a molding compound surrounding the first die, the second die, and the dummy die structure, wherein the molding compound is in contact with the interposer.
